(19) United States
(12) Patent Application Publication
(10) Pub. No.: US 2007/0184657 A1
(43) Pub. Date: Aug. 9, 2007

(54) ETCHING METHOD

(75) Inventors: Etsuo IIJIMA, Amagasaki-shi (JP); Takamichi KIKUCHI, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/671,129

(22) Filed: Feb. 5, 2007

Related U.S. Application Data
(60) Provisional application No. 60/774,205, filed on Feb. 17, 2006.

(30) Foreign Application Priority Data
Feb. 9, 2006 (JP) 2006-031839

(51) Int. Cl. C03C 25/68; G06F 19/00; H01L 21/306; H01L 21/302

(52) U.S. Cl. 438/689; 700/121; 156/345.24; 216/58

(57) ABSTRACT

An etching method includes the step of forming recesses by performing a plasma etching on a target layer of a target object in a processing chamber of a plasma processing apparatus. The plasma etching is performed by using a mask, which is formed on the target layer and is provided with opening patterns including a dense patterned region and a sparse patterned region, such that portions of the target layer exposed through the opening pattern are etched by a plasma to form the recesses; and the plasma is exited by introducing a processing gas. A ratio of a flow rate of HBr to a flow rate of Cl₂ (HBr/Cl₂) is greater than or equal to about 1.2 and a ratio of a flow rate of the fluorine-containing gas to the flow rate of HBr (fluorine-containing gas/HBr) is greater than or equal to about 1.0.

### FIELD OF THE INVENTION

The present invention relates to an etching method; and, more particularly, to an etching method for etching the silicon of a target object to be processed with a high etching profile controllability.

### BACKGROUND OF THE INVENTION

A manufacturing process of a polysilicon gate electrode involves a dry etching for a polysilicon layer formed on a target object to be processed such as a semiconductor wafer by employing a previously formed resist pattern as a mask. During the dry etching, a plasma is excited by employing a gas system containing, for example, Cl₂ and HBr as a main etching gas (see, e.g., Patent References 1 and 2).

With a recent trend of miniaturization and high integration of semiconductor devices, a target object having both sparse and dense mask patterns is required to be etched with a high etching profile controllability. However, when using the above conventional gas system, the resulting etching profiles of the dense and the sparse patterned regions have been found to be different from each other.

The gas system containing Cl₂ and HBr reacts with the silicon to be etched, thereby generating reaction products such as SiClₓ and SiBrₓ. Such reaction products stick to the sidewall portions of etching grooves and function as a protective film to suppress side etching. Since, however, the widths of the etching grooves are small in the dense patterned region, the etching area is also small. Thus, the amount of reaction products adhered to the sidewall portions of the etching grooves is restricted in proportion thereto and the protection therefor is weakened. Meanwhile, in the sparse patterned region, since the widths of the etching grooves are large, the etching area is large as well. Accordingly, a greater amount of the reaction products sticks to the sidewall portions of the etching grooves, and the protection is thus enhanced. As a result, there occur problems that the dense patterned region is more likely subject to the side etching and that the sparse patterned region is not etched sufficiently. Therefore, the sidewalls of the grooves, which are required to be vertical, would be formed in reverse-taper shapes (or overhang shapes) and tapered shapes in the dense and the sparse patterned region, respectively.

### [Patent Reference 1]

Japanese Patent Laid-open Application No. 2004-266249 (for example, Paragraph No. 0034)

### [Patent Reference 2]

Japanese Patent Laid-open Application No. 2005-79289 (for example, Paragraph No. 0047)

Patent Reference 1 discloses an etching process using the gas system containing Cl₂, HBr, and CF₄ (for example, Cl₂/HBr/CF₄ or Cl₂/HBr/CF₄/O₂). However, the gas system mainly deals with the selectivity against an oxide film, without considering the etching profile control for a pattern having both the dense and the sparse patterned regions.

Further, Patent Reference 2 describes a dry etching of a polysilicon film by using the gas system containing Cl₂, HBr, CF₄ and O₂. However, the gas system is selected to create a condition that the selectivity of the polysilicon film to a gate oxide film is low and is not configured to control the etching profile for a pattern having both the dense and the sparse patterned regions.

### SUMMARY OF THE INVENTION

It is, therefore, an object of the present invention to provide an etching method capable of etching a polysilicon layer on a target object to be processed with a high controllability even if sparse and dense patterns coexist.

In accordance with a first aspect of the present invention, there is provided an etching method, including the steps of: forming recesses by performing a plasma etching on a target layer of a target object in a processing chamber of a plasma processing apparatus, wherein the plasma etching is performed by using a mask, which is formed on the target layer and is provided with opening patterns including a dense patterned region having a narrower opening width and a sparse patterned region having a wider opening width, such that portions of the target layer exposed through the opening pattern are etched by a plasma to form the recesses; and the plasma is exited by introducing a processing gas including at least Cl₂, HBr and a fluorine-containing gas selected from CF₄, CHF₃, SF₆ and NF₃, a ratio of a flow rate of HBr to a flow rate of Cl₂ (HBr/Cl₂) being greater than or equal to about 1.2 and a ratio of a flow rate of the fluorine-containing gas to the flow rate of HBr (fluorine-containing gas/HBr) being greater than or equal to about 1.0.

Sidewall angles of the recesses may not exceed 90°, and a difference in sidewall angles of recesses formed in the sparse patterned region and sidewall angles of recesses formed in the dense patterned region may be less than or equal to about 16°.

It is preferable that the target layer may be a polysilicon layer. It is also preferable that a ratio of the opening width of the sparse patterned region to the opening width of the dense patterned region may be greater than or equal to about 10.

In accordance with a second aspect of the present invention, there is provided a computer executable control program, which controls, when executed, the plasma processing apparatus to perform the etching method.

In accordance with a third aspect of the present invention, there is provided a computer-readable storage medium for storing therein a computer executable control program, wherein, when executed, the control program controls the plasma processing apparatus to perform the etching method.

In accordance with a fourth aspect of the present invention, there is provided a plasma processing apparatus including a processing chamber for performing a plasma etching on a target object; a support for mounting thereon the target object in the plasma processing chamber; a gas exhaust unit for depressurizing the processing chamber; a gas supply unit for supplying a processing gas into the processing chamber; and a control unit for controlling the etching method to be carried out in the processing chamber.

In accordance with a fifth aspect of the present invention, there is provided a manufacturing method for a semiconductor device including the etching step of forming recesses by performing an etching on a target object having an insulating film formed on a substrate and a polysilicon layer formed on the insulating film, wherein the etching is performed by using a mask, which is formed on the polysilicon layer and is provided with opening pattern including a dense patterned region having a narrower opening width and a sparse pattern region having a wider opening width, such that portions of the polysilicon layer exposed through the opening pattern are etched to form the recesses; and a plasma is exited by introducing a processing gas at least containing Cl₂, HBr and a fluorine-containing gas selected from CF₄ and CHF₃, a ratio of a flow rate of HBr to a flow rate of Cl₂ (HBr/Cl₂) being greater than or equal to about 1.2 and a ratio of a flow rate of the fluorine-containing gas to the flow rate of HBr (fluorine-containing gas/HBr) being greater than or equal to about 1.0.

Sidewall angles of the recesses may not exceed 90°, and a difference in sidewall angles of recesses formed in the sparse patterned region and sidewall angles of recesses formed in the dense patterned region may be less than or equal to about 16°.

In accordance with the etching method of the present invention, even a target object having both a dense mask pattern and a sparse mask pattern can be uniformly etched with a high etching profile controllability by employing a processing gas, which includes at least, Cl₂, HBr and a fluorine containing gas selected from CF₄ and CHF₃ at a preset flow rate. Therefore, the method can be applied to a field where miniaturization and high integration of semiconductor devices are required.

### BRIEF DESCRIPTION OF THE DRAWINGS

The above and other objects and features of the present invention will become apparent from the following description of exemplary embodiments given in conjunction with the accompanying drawings, in which:

FIG. 1 is a schematic cross sectional view of a semiconductor wafer to which an etching method of the present invention is applied;

FIG. 2 sets forth a schematic cross sectional view of a semiconductor wafer processed by the etching method of the present invention;

FIG. 3 is a schematic cross sectional view of a semiconductor wafer processed by a conventional etching method;

FIG. 4 offers a cross sectional view of a parallel plate type plasma etching apparatus suitable for performing the etching method of the present invention;

FIG. 5 depicts a schematic horizontal cross sectional view of multipole ring magnets disposed around a chamber of the etching apparatus of FIG. 4; and

FIGS. 6A to 6C provide diagrams which demonstrate rotational motions of the segment magnets of FIG. 4 and their resulting variations in a magnetic field.

### DETAILED DESCRIPTION OF THE EMBODIMENTS

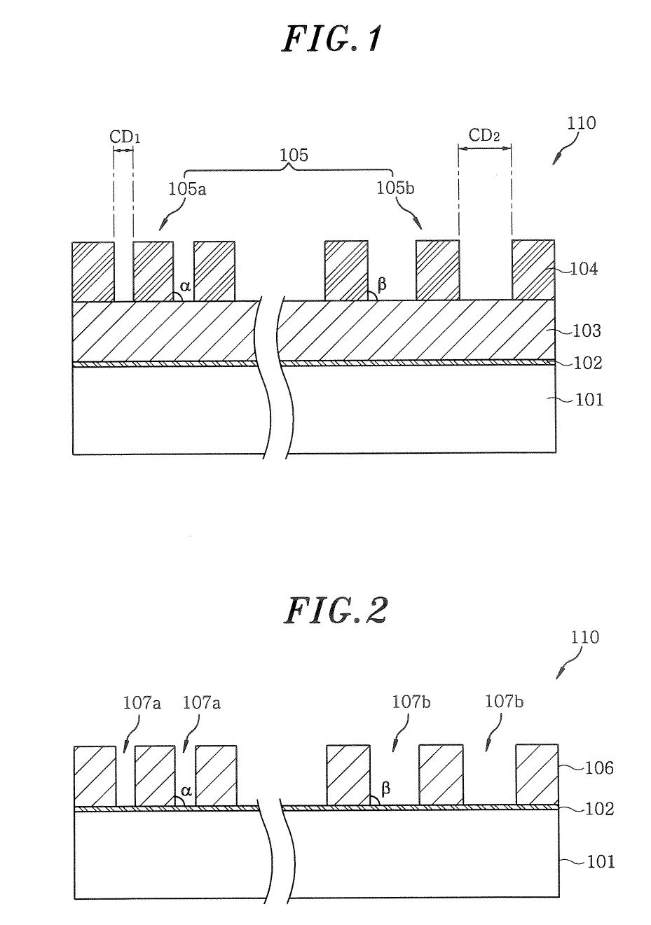

Hereinafter, embodiments of the present invention will be described with reference to the accompanying drawings. FIG. 1 schematically illustrates a cross sectional configuration of a target object 110 to be processed, e.g., a semiconductor wafer W, to which an etching method of the present invention is applied. The target object 110 is used in manufacturing, for example, gate electrodes for MOS transistors. As for the configuration of the target object 110, a gate insulating film 102 made of, e.g., SiO₂ is formed on a Si substrate 101 which includes therein N-type or P-type diffusion layers (not shown) formed by ion implantation and device isolation layers (not shown). Further, a polysilicon layer 103 is formed on the gate insulating film by, for example, CVD. A mask layer 104 made of, for example, SiO₂ by a TEOS (tetraethoxysilane) process is formed as required on the polysilicon layer 103 having impurities such as phosphorous and boron implanted thereinto. Further, a mask pattern 105 of lines and spaces is formed in advance in the mask layer 104 by a photolithography process, wherein the mask pattern 105 includes dense and sparse patterned regions 105a and 105b.

That is, the mask film 104 has a dense patterned region 105a having small pattern gaps and a sparse patterned region 105b having large pattern gaps. In this regard, no restriction is set on the pattern gaps of the dense patterned region 105a and the sparse patterned region 105b. However, effects of an embodiment of the present invention to be described later can be obtained advantageously if the ratio of an opening width CD₁ at the dense patterned region 105a to an opening width CD₂ at the sparse patterned region 105b is greater than 1:10. Further, the opening width CD₁ of the dense patterned region 105a may be between 50 to 200 nm, while the opening width CD₂ at the sparse patterned region 105b may be wider than 500 nm, for example.

By plasma etching the target object 110 having the above configuration in accordance with the method of the present invention, narrow grooves 107a and wide grooves 107b are formed along the both sides of polysilicon electrodes 106 according to the density in pattern gaps as illustrated in FIG. 2, wherein the polysilicon electrodes 106 serves as gate electrodes.

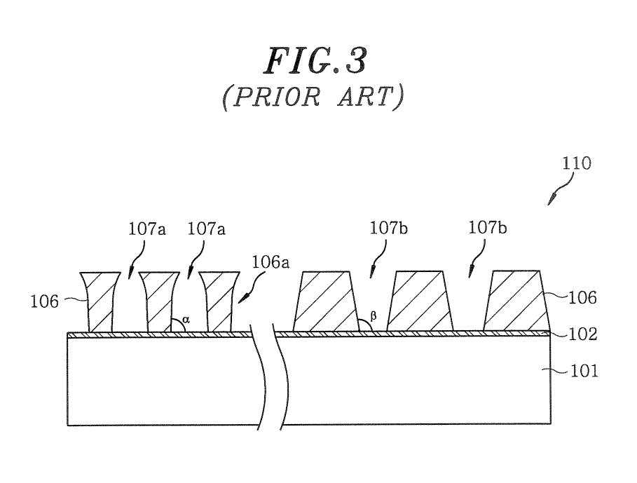

In case of etching by employing a conventional etching gas system of, e.g., a Cl₂/HBr/O₂/rare gas, there occurs a difference in etched profile of the polysilicon electrodes 106 due to the different widths CD₁ and CD₂ in the mask pattern 105. That is, side etched portions 106a would be formed at the sidewall portions of the polysilicon electrodes 106 separated by the narrow grooves 107a, and the sidewall angle (180°-α) thereof becomes greater than a right angle (90°) to have a reverse taper shape (or overhang shape) as shown in FIG. 3. On the other hand, because the etching area is large for the polysilicon electrodes 106 separated by the wide grooves 107b, a large amount of reaction products SiClₓ and SiBrₓ sticks to the sidewalls thereof, thereby serving as protective films. As a result, as shown in FIG. 3, the sidewall angle (180°-β) becomes smaller than a right angle (90°), and the wide grooves 107b would have taper-shaped cross sections.

When using a conventional etching gas of Cl₂ and HBr, the control of etching profile is conducted by employing the reaction products SiClₓ and SiBrₓ generated by the reaction with the etching target film of polysilicon as sidewall protective films. However, as the difference in mask pattern density increases, the difference in size of etching area increases as well, which in turn causes the amount of the reaction products to vary. That is, in the dense patterned region 105a, since the etching area is relatively small, the amount of the reaction products is also small, and the amount of the reaction products adhered to the sidewalls decreases accordingly. Thus, the protection offered by the reaction products would not be sufficient, thereby causing the polysilicon etching to progress in lateral directions, which in turn causes the side etched portions 106a to be easily formed at the sidewall portions of the polysilicon electrodes 106. On the contrary, since the etching area is relatively large in the sparse patterned region 105b, the amounts of the reaction products generated and adhered to the sidewalls thereof would increase, thereby enhancing the protection, which in turn suppresses etching of the polysilicon. For these reasons, the difference in pattern density dictates the difference in etching profile as shown in FIG. 3. Since such difference in etching profile affect device characteristics, it is desired that the problem of etching profile variation be solved.

To solve the above problem, an etching gas containing, at least, Cl₂, HBr and a fluorine containing gas selected from CF₄ and CHF₃ is employed as a processing gas in an etching method in accordance with the embodiment of the present invention. For example, the CF₄ gas can easily form a CFₓ (polymer), and the resulting polymer would stick to the sidewalls of the polysilicon electrodes 106 to function as protective films. That is, unlike the Cl₂ gas and the HBr gas, which generate SiClₓ and SiBrₓ by reacting with the etching polysilicon, the CF₄ gas forms the polymers, which are capable of functioning as the protection films without reacting with the polysilicon. Therefore, the polymers can uniformly stick to the surface of a to-be-etched film without depending on the variation in the pattern density (i.e., the size of the etching area). Further, as the CFₓ adheres to the surface of the to-be-etched film, SiClₓ and SiBrₓ are suppressed from even being generated, which in turn provides uniform etching profile across the entire surface of the wafer W, as illustrated in FIG. 2, while unaffected by the difference in the size of the etching area biased on the pattern density.

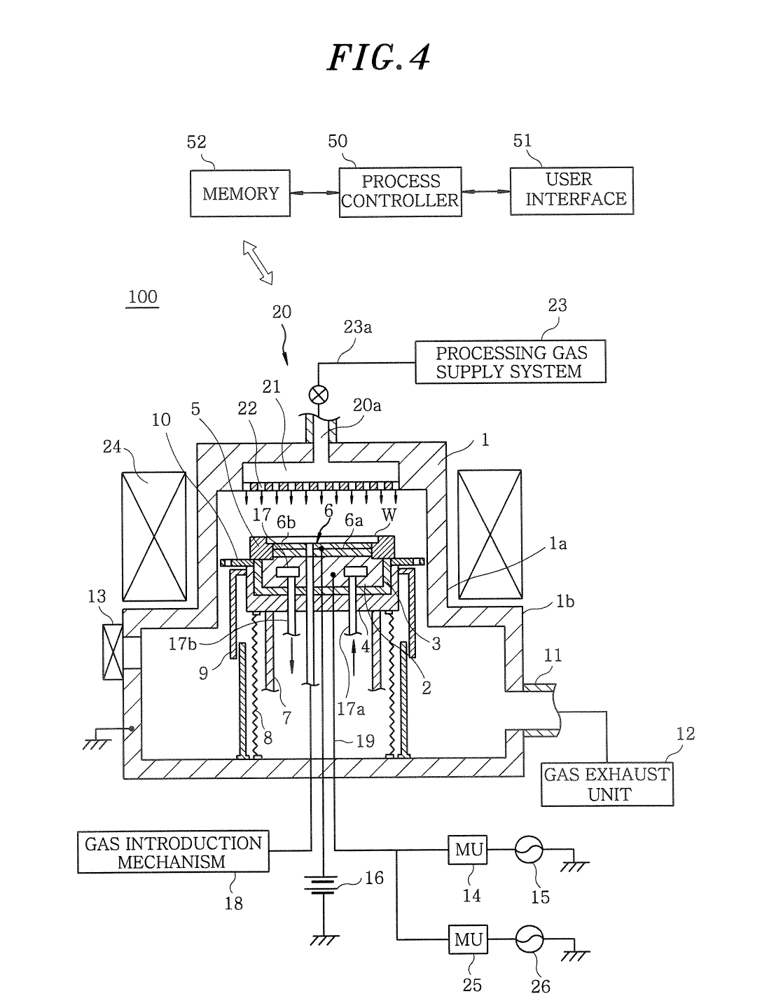

In such a case, to prevent the dense patterned region from being side-etched, it is preferable to supply HBr and Cl₂ into a chamber 1 (see FIG. 4) of a plasma etching apparatus while maintaining a ratio between their flow rates (HBr/Cl₂) to be greater than or equal to 1.2.

Further, to reduce etching profile variances in the sparse and the dense patterned region resulting from the difference in the pattern density (in particular, to reduce the difference in the sidewall angles (180°-α) and (180°-β)), it is preferable that a fluorine containing gas, e.g. CF₄, and an HBr gas be supplied into the chamber while maintaining the ratio between their flow rates (the fluorine containing gas/HBr) to be greater than or equal to 1.0.

By using the above etching gas, a sufficiently uniform etching can be performed advantageously even on a target object in which a ratio between the opening width CD₁ of the dense patterned region 105a and the opening width CD₂ of the sparse patterned region 105b is 1:10 or greater. To be more specific, the etching profile can be controlled such that both the sidewall angles of the grooves 107a and 107b formed at regions exposed through the opening patterns do not exceed 90° while the difference between the sidewall angle of the grooves 107b at the sparse patterned region 105b and the sidewall angle of the grooves 107a at the dense patterned region 105a is preferably less than or equal to 16°.

After forming gate electrodes (polysilicon electrodes 106) via the above etching process, transistors can be produced by forming P-type or N-type diffusion layers (not shown) serving as source/drain regions through implantation of impurities.

Hereinafter, an etching method in accordance with the embodiment of the present invention will be described, FIG. 4 illustrates a configuration of a parallel plate type plasma etching apparatus 100 adequate for performing the etching method in accordance with the embodiment of the present invention. The etching apparatus 100 includes a chamber (processing vessel) 1 having a wall made of, for example, aluminum. The chamber 1 is hermetically sealed and is configured to have a stepped cylindrical shape with an upper portion 1a having a smaller diameter and a lower portion 1b having a larger diameter.

Installed in the chamber 1 is a supporting table 2 for horizontally supporting the wafer W, the wafer W being a single crystalline Si substrate functioning as a target object. The supporting table 2 is made of, for example, aluminum and is supported by a conductive support 4 via an insulator 3. Furthermore, a focus ring 5 formed of, for example, Si is mounted on the periphery of the top surface of the supporting table 2. The supporting table 2 and the support 4 are configured to move up and down by a ball screw mechanism having ball screws 7. Further, the driving portion thereof located below the support 4 is covered with a stainless steel (SUS) bellows 8, and a bellows cover 9 is installed to enclose the bellows 8. Also, a baffle plate 10 is installed outside the focus ring 5, and the focus ring 5 is electrically connected to the chamber 1 via the baffle plate 10, the support 4 and the bellows 8. The chamber 1 is grounded.

A gas outlet port 11 is formed at the sidewall of the lower portion 1b in the chamber 1, and a gas exhaust system 12 is connected to the gas outlet port 11. By operating a vacuum pump of the gas exhaust system 12, the chamber 1 is depressurized to a specific vacuum level. Further, a gate valve 13 for opening and closing a loading/unloading port for the wafer W is installed at the upper sidewall of the lower portion 1b in the chamber 1.

A first high frequency power supply 15 for plasma generation is connected to the supporting table 2 via a matching unit 14 (MU), and a high frequency power at a specific frequency is applied to the supporting table 2 from the first high frequency power supply 15. Further, an electrically grounded shower head 20 to be described later in detail is disposed above the supporting table 2 while facing the supporting table 2 in parallel. Accordingly, the supporting table 2 and the shower head 20 are configured to function as a pair of electrodes.

A second high frequency power supply 26 is connected to the power feed line of the first high frequency power supply 15 via a matching unit (MU) 25. The second high frequency power supply 26 applies a high frequency power whose frequency is lower than the one from the first high frequency power supply 15, so that it is superposed upon the high frequency power for the plasma generation.

An electrostatic chuck 6 for electrostatically attracting and holding the wafer W thereon is provided on the top surface of the supporting table 2. The electrostatic chuck 6 has an electrode 6a embedded in an insulator 6b, and the electrode 6a is connected to a DC power supply 16. By applying a voltage to the electrode 6a from the DC power supply 16, an electrostatic force, e.g., a Coulomb force, is generated, thereby attracting and holding the wafer W.

A coolant path 17 is formed inside the supporting table 2 to continuously introduce a coolant via a coolant introducing line 17a and discharge via a coolant discharge line 17b. By this circulation of the coolant, the cold heat of the coolant is transferred from the supporting table 2 to the wafer W, whereby the processing surface of the wafer W is maintained at a desired temperature level.

Further, a cooling gas is introduced between the top surface of the electrostatic chuck 6 and the rear surface of the wafer W from a gas introduction mechanism 18 via a gas supply line 19 in order to effectively cool the wafer W with the coolant circulated in the coolant path 17 even if the chamber 1 is pumped by the gas exhaust system 12 to be maintained in a vacuum state. By introducing the cooling gas, the cold heat of the coolant is efficiently transferred to the wafer W, thereby improving the cooling efficiency for the wafer W. He can be employed as the cooling gas, for example.

The shower head 20 is disposed at the ceiling of the chamber 1 while facing the supporting table 2. The shower head 20 is provided with a plurality of gas discharge openings 22 at its lower surface and includes a gas inlet 20a at the upper portion thereof. Further, the shower head 20 has a hollow space 21 formed therein. One end of a gas supply line 23a is connected to the gas inlet 20a, and the other end thereof is connected to a processing gas supply system 23 which serves to supply a processing gas containing an etching gas and a dilution gas.

The processing gas is introduced into the space 21 of the shower head 20 from the processing gas supply system 23 via the gas supply line 23a and the gas inlet 20a so as to be discharged through the gas discharge openings 22.

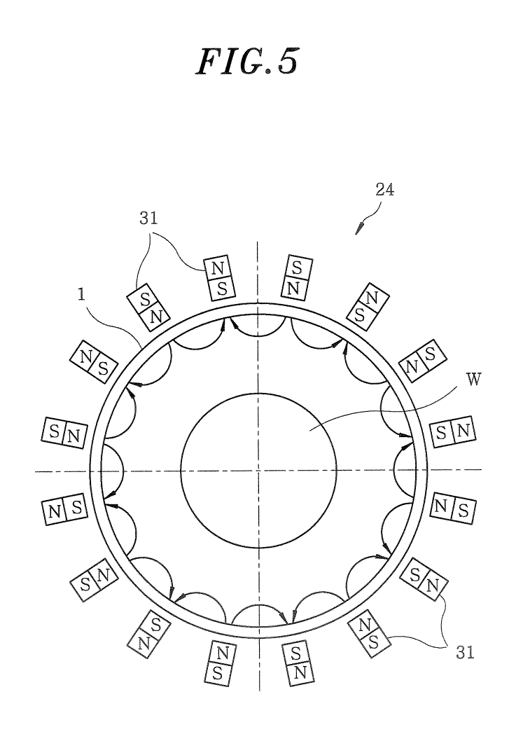

Concentrically disposed around the periphery of the upper portion 1a of the chamber 1 is a multipole magnet unit 24 that serves to form a magnetic field around a processing space between the supporting table 2 and the shower head 20. The multipole magnet unit 24 can be rotated by a rotation mechanism (not shown) As shown in the plan view of FIG. 5, the multipole magnet unit 24 includes a plurality of segment magnets 31 that are permanent magnets annularly arranged while being supported by a supporting member (not shown). In this example, sixteen segment magnets 16 are annularly (concentrically) arranged while maintaining a multipole state. In particular, in the multipole magnet unit 24, the magnetic pole directions of every two neighboring segment magnets 31 are arranged to be opposite to each other. Therefore, magnetic lines of force are formed between the neighboring segment magnets 31 as shown in FIG. 5, and a magnetic field whose strength ranges from, e.g. 0.02 to 0.2 T (200 to 2000 Gauss), but preferably 0.03 to 0.045 T (300 to 450 Gauss), is formed only around the peripheral region of a processing space. Therefore, virtually no magnetic field exists at the region where the wafer W is located. Here, if the magnetic field strength is excessively high, the magnetic field would leak, whereas if the magnetic field strength is excessively low, the plasma cannot be confined effectively. These are the reasons for maintaining the magnetic field strength within the above prescribed range. However, the above-specified range of the magnetic field strength is only one example that can be varied, for example, depending on the structure of the apparatus. Accordingly, the magnetic field strength is not limited thereto. The above disclosed clause “virtually no magnetic field exists at the region where the wafer W is located” includes not only a case where completely no magnetic field exist at the region, but also refers to a case where only a negligible magnetic field exists at the region that does not in effect affect the etching process of the wafer W.

In the configuration shown in FIG. 5, a magnetic field having a magnetic flux density of no more than, e.g., 420 μT (4.2 Gauss) is applied on and around the wafer, thereby effectively confining the plasma.

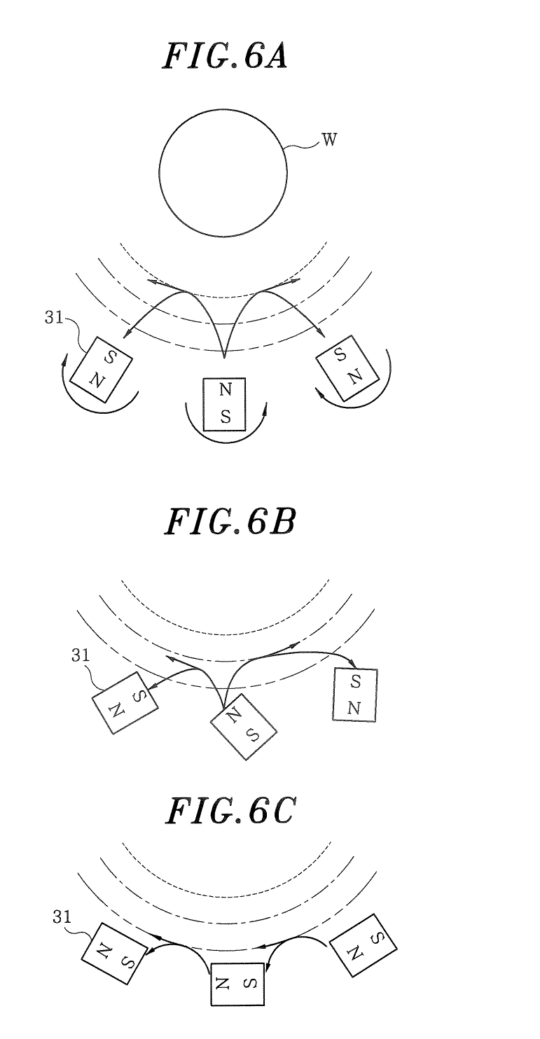

Each of the segment magnets 31 is configured to freely rotate about its vertical axis by a segment magnet rotating unit (not shown). Initially, a pole of each segment magnet is directed toward the chamber 1 as illustrated in FIGS. 5 and 6A, and two neighboring segment magnets 31 are synchronously rotated in opposite directions, as shown in FIGS. 6B and 6C, for example. Therefore, every other segment magnet 31 is rotated in a same direction. FIGS. 6B and 6C show the segment magnets 31 rotated at 45 and 90 degrees, respectively. By rotating the segment magnets 31 as described above, it is possible to switch between the states where an effective multipole magnetic field is formed and not formed. Depending on the types of etching films, the multipole magnetic field can or cannot work effectively. Therefore, an optimal etching condition can be selected depending on the types of the etching films by switching between such states of multipole magnetic field.

Each component of the plasma etching apparatus 100 is coupled to and controlled by a process controller 50 having a CPU. A user interface 51 is connected to the process controller 50, wherein the user interface 51 includes, e.g., a keyboard for a process manager to input a command to operate the plasma etching apparatus 100, a display for showing an operational status of the plasma etching apparatus 100, and the like.

Moreover, connected to the process controller 50 is a memory 52 for storing therein, e.g., control programs and recipes including processing condition data and the like to be used in realizing various processes, which are performed in the plasma etching apparatus 100 under the control of the process controller 50.

When a command is received from the user interface 51, the process controller 50 retrieves a necessary recipe from the memory 52 as required to execute the command to perform a desired process in the plasma processing apparatus 100 under the control of the process controller 50. The necessary recipe can be retrieved from a computer-readable storage medium such as a CD-ROM, a hard disk, a flash memory, a flexible disk or the like, or can be transmitted from another apparatus via, e.g., a dedicated line, if necessary.

Hereinafter, the etching method in accordance with the embodiment of the present invention, which is performed by the plasma etching apparatus 100 configured as described above, will be explained. First, the gate valve 13 is opened, and a wafer W is loaded into the chamber 1 and mounted on the supporting table 2. Then, the supporting table 2 is elevated up to a position illustrated in FIG. 4, and the chamber 1 is evacuated via the gas outlet port 11 by the vacuum pump of the gas exhaust system 12.

A processing gas, which includes at least an etching gas, is supplied into the chamber 1 from the processing gas supply system 23 at a specific flow rate. Then, while maintaining the internal pressure of the chamber 1 at a specific pressure level, a predetermined high frequency power is applied to the supporting table 2 from the first high frequency power supply 15. At this time, the wafer W is attracted and held by, e.g., a Coulomb force generated by a specific voltage applied to the electrode 6a of the electrostatic chuck 6 from the DC power supply 16, and a high frequency electric field is formed between the shower head 20 serving as an upper electrode and the supporting table 2 serving as a lower electrode. As a result, the processing gas supplied into the processing space is converted into a plasma, and a polysilicon layer 103 on the wafer W is etched by the plasma. During the etching process, a magnetic field is formed by the multipole magnet unit 24 as illustrated in FIG. 5, whereby the plasma is effectively confined to achieve a uniform etching rate of the wafer W.

To obtain the uniform etching profile, a gas containing Cl₂ and HBr is employed together with a fluorine-containing gas as the etching gas. It is preferable that the fluorine-containing gas has a large number of fluorine atoms (F) per a single molecule. For example, CF₄, CHF₃, SF₆, and NF₃, and the like are preferably employed. Further, by using an oxygen gas together with the fluorine-containing gas, the etching anisotropy can be enhanced and thus etching profile can be improved.

To improve the etching profile, it is also effective to control the temperature of the wafer W. To achieve this controllability, there is provided the coolant path 17 which circulates the coolant therethrough. In this manner, the cold heat of the coolant is transferred to the wafer W through the supporting table 2 so as to maintain the processing surface of the wafer W at a desired temperature. To improve the etching profile, i.e. the etching anisotropy, it is preferable that the temperature of the wafer W is regulated at, e.g., about 30 to 90° C.

The frequency and the output of the first high frequency power supply 15 for plasma generation is properly set to generate a desired plasma. To increase the density of the plasma directly above the wafer W, its frequency is preferably set to be greater than or equal to 40 MHz.

The second high frequency power supply 26 serves to supply a high frequency power to control the ion energy of the plasma. Its frequency is preferably set to be smaller than the frequency of the first high frequency power supply 15 while being greater than or equal to 3.2 MHz.

By selecting the type and the flow rate of the etching gas as described above in the etching process, the etching profile can be uniformly obtained. Further, other preferred ranges for the process parameters are as follows. The internal gas pressure of the chamber 1 is set to be about 0.13 to 6.67 Pa (1 to 50 mTorr); the frequencies of the first and the second high frequency power supply 15 and 26 are set to be about 100 MHz and about 13 MHz, respectively; the strength of the magnetic field formed in the processing space by the multipole magnet unit 24 is set to be about 5.6 to 45.4 μT (56 to 454 Gauss). By employing the above conditions, the etching profiles of the wafer W can be uniformly produced regardless of the difference in the mask pattern density.

Now, the experiment results on etching profiles obtained by etching a wafer W while changing compositions of an etching gas will be explained.

An target object was etched by using the parallel plate type plasma etching apparatus 100 shown in FIG. 4, wherein the target object had, on the surface of a wafer W, a gate insulating film 102, a polysilicon layer 103 and a mask film 104 formed of SiO₂ (TEOS) and having a mask pattern of lines and spaces having dense and sparse patterned regions. Etching profiles were inspected based on SEM images by considering the sidewall angels (180°-an angle formed between a sidewall and a bottom surface of a groove) and presence/absence of side etching.

While setting the internal pressure of the chamber 1 to 0.67 Pa (5 mTorr) during etching, a combination of Cl₂/HBr/O₂/CF₄ was used as an etching gas in the chamber 1. While maintaining the flow rate of the O₂ gas at 1 mL/min (sccm), the flow rates of the Cl₂, HBr and CF₄ gases were varied as shown in Table 1. Further, the frequencies of the first high frequency power supply 15 and the second high frequency power supply 26 were set to be 100 MHz and 13 MHz, respectively, and the outputs from the first high frequency power supply 15 and the second high frequency power supply 26 were set to be 100 W and 200 W, respectively. Also, in order to effectively cool the wafer W, a cooling gas was supplied to the central portion of the wafer W at a back pressure of 1333 Pa (10 Torr) and to the edge portion of the wafer W at a back pressure of 4000 Pa (30 Torr) to maintain the temperature of the wafer W at 30° C. Further, the temperatures of the shower head 20 and the sidewall of the chamber 1 were set at 80° C. and 70° C., respectively. The widths of the grooves formed by etching were 0.05 μm and 0.03 μm.

TABLE 1

| | CF₄/HBr Flow Rate | | CF₄/HBr Flow Rate | | CF₄/HBr Flow Rate | |
|---|---|---|---|---|---|---|
| | 30/70 mL/min | | 60/40 mL/min | | 90/10 mL/min | |
| | (sccm) | | (sccm) | | (sccm) | |
| | Dense PR | Sparse PR | Dense PR | Sparse PR | Dense PR | Sparse PR |
| Cl₂ | 99.3° | 82.0° | 94.2° | 82.4° | 96.7° | 86.3° |
| Flow Rate | Side Etching Occured | Side Etching Absent | Side Etching Occured | Side Etching Absent | Side Etching Occured | Side Etching Absent |

| 60 mL/min | Angle Difference 17.3° | | Angle Difference 11.8° | | Angle Different 10.4° |
|---|---|---|---|---|---|
| (sccm) | | | | | |
| | | | CF₄/HBr Flow Rate | | |
| | | | 60/55 mL/min | | |
| | | | (sccm) | | |
| | | | Dense PR | Sparse PR | |
| Cl₂ | | | 87.5° | 71.9° | |
| Flow Rate | | | Side Etching Absent | Side Etching Absent | |
| 45 mL/min | | | Angle Difference 15.6° | | |
| (sccm) | | | | | |
| | CF₄/HBr Flow Rate | | CF₄/HBr Flow Rate | | |
| | 30/100 mL/min | | 60/70 mL/min | | |
| | (sccm) | | (sccm) | | |
| | Dense PR | Sparse PR | Dense PR | Sparse PR | |
| Cl₂ | 89.0° | 69.1° | 86.6° | 68.1° | |
| Flow Rate | Side Etching Absent | Side Etching Absent | Side Etching Absent | Side Etching Absent | |

| | | |
|---|---|---|
| 30 mL/min | Angle Difference 19.9° | Angle Difference 18.5° |
| (sccm) | | |

Dense PR: Dense Patterened Region
Sparse PR: Sparse Patterened Region

Table 1 shows sidewall angles obtained in various processing conditions. As the ratio of the flow rate of CF₄ to the flow rate of HBr decreases, the difference in the sidewall angles caused by the difference in the pattern density are observed to increase. Such trend is deemed to be due to insufficient sidewall protection of CF₄ and pattern density dependent variations in the etching process caused by the variations in the amount of adhered reaction products, such as SiClₓ and SiBrₓ, owing to the difference in the etching areas.

It is also confirmed that, if the flow rate of Cl₂ is small, the cross sections of the grooves become tapered, and the sidewall angles of the grooves decrease and the difference between the sidewall angles due to pattern density tends to be increased. In contrast, if the flow rate of Cl₂ is large, the sidewall angles increase and the sidewall angle exceed 90° at the dense patterned regions, causing side etching.

Furthermore, if the ratio for the flow rate of CF₄ to the flow rate of HBr is small and so is the flow rate of Cl₂, etching rate becomes low at the sparse patterned region, and the difference in the sidewall angles due to pattern density increases.

Moreover, if the flow rate of Cl₂ and a ratio of the flow rate of CF₄ to the flow rate of HBr are large the difference in the sidewall angles due to pattern density reduces. However, side etching becomes very noticeable.

As described in the above, by employing the etching method in accordance with the embodiment of the present invention, etching profiles can be uniformly obtained advantageously when performing an etching on a pattern having dense and sparse patterned regions.

Here, it is to be noted that the present invention is not limited to the embodiment described above but can be modified in various ways. For example, though the multipole magnet unit has been employed to generate a magnetic field for the parallel plate type plasma etching apparatus in the above embodiment, the magnetic field generation means is not limited thereto and the formation of the magnetic field is neither essential. Further, as long as a plasma can be formed by the types of gases of the present invention, various types of plasma etching apparatuses, such as a capacitively coupled plasma etching apparatus, an inductively coupled plasma etching apparatus and a microwave plasma etching apparatus, can be employed.

While the invention has been shown and described with respect to the embodiments, it will be understood by those skilled in the art that various changes and modifications may be made without departing from the scope of the invention as defined in the following claims.

What is claimed is:

1. An etching method, comprising the steps of:
forming recesses by performing a plasma etching on a target layer of a target object in a processing chamber of a plasma processing apparatus,
wherein the plasma etching is performed by using a mask, which is formed on the target layer and is provided with opening patterns including a dense patterned region having a narrower opening width and a sparse patterned region having a wider opening width, such that portions of the target layer exposed through the opening pattern are etched by a plasma to form the recesses; and the plasma is exited by introducing a processing gas including at least Cl₂, HBr and a fluorine-containing gas selected from CF₄, CHF₃, SF₆ and NF₃, a ratio of a flow rate of HBr to a flow rate of Cl₂ (HBr/Cl₂) being greater than or equal to about 1.2 and a ratio of a flow rate of the fluorine-containing gas to the flow rate of HBr (fluorine-containing gas/HBr) being greater than or equal to about 1.0.

2. The etching method of claim 1, wherein sidewall angles of the recesses do not exceed 90°, and a difference in sidewall angles of recesses formed in the sparse patterned region and sidewall angles of recesses formed in the dense patterned region is less than or equal to about 16°.

3. The etching method of claim 1, wherein the target layer is a polysilicon layer.

4. The etching method of claim 1, wherein a ratio of the opening width of the sparse patterned region to the opening width of the dense patterned region is greater than or equal to about 10.

5. A computer executable control program, which controls, when executed, the plasma processing apparatus to perform the etching method of claim 1.

6. A computer-readable storage medium for storing therein a computer executable control program, wherein, when executed, the control program controls the plasma processing apparatus to perform the etching method of claim 1.

7. A plasma processing apparatus comprising:
a processing chamber for performing a plasma etching on a target object;
a support for mounting thereon the target object in the plasma processing chamber;
a gas exhaust unit for depressurizing the processing chamber;
a gas supply unit for supplying a processing gas into the processing chamber; and
a control unit for controlling the etching method of claim 1 to be carried out in the processing chamber.

8. A manufacturing method for a semiconductor device comprising the etching step of:
forming recesses by performing an etching on a target object having an insulating film formed on a substrate and a polysilicon layer formed on the insulating film,
wherein the etching is performed by using a mask, which is formed on the polysilicon layer and is provided with opening pattern including a dense patterned region having a narrower opening width and a sparse pattern region having a wider opening width, such that portions of the polysilicon layer exposed through the opening pattern are etched to form the recesses; and a plasma is exited by introducing a processing gas at least containing Cl₂, HBr and a fluorine-containing gas selected from CF₄ and CHF₃, a ratio of a flow rate of HBr to a flow rate of Cl₂ (HBr/Cl₂) being greater than or equal to about 1.2 and a ratio of a flow rate of the fluorine-containing gas to the flow rate of HBr (fluorine-containing gas/HBr) being greater than or equal to about 1.0.

9. The manufacturing method of claim 8, wherein sidewall angles of the recesses do not exceed 90°, and a difference in sidewall angles of recesses formed in the sparse patterned region and sidewall angles of recesses formed in the dense patterned region is less than or equal to about 16°.
